(19) United States
(12) Patent Application Publication
(10) Pub. No.: US 2025/0043427 A1
(43) Pub. Date: Feb. 6, 2025

(54) WAFER PROCESSING APPARATUS WITH AUXILIARY GROUND PATHS

(71) Applicant: ASM IP Holding B.V., Almere (NL)

(72) Inventors: Songwhe Herr, Seongnam-si (KR); Dongok Shin, Suwon (KR); KiChul Um, Osan-si (KR)

(21) Appl. No.: 18/785,394

(22) Filed: Jul. 26, 2024

Related U.S. Application Data
(60) Provisional application No. 63/530,025, filed on Jul. 31, 2023.

(51) Int. Cl. C23C 16/505; C23C 16/455

(52) U.S. Cl. CPC C23C 16/505; C23C 16/45565

(57) ABSTRACT

A wafer processing apparatus with improved film uniformity is presented. The apparatus comprising a radio frequency (RF) enclosure enclosing and defining a reaction chamber; a showerhead placed inside of the reaction chamber configured to generating plasma for processing a wafer in the reaction chamber; a radio frequency (RF) power supply configured to generate RF and supply the generated RF to the showerhead; a plurality of capacitors connected in parallel and/or in serial between the RF power supply and the showerhead; and more than one auxiliary ground lines configured to be placed above the showerhead. The auxiliary ground lines are to be turned on sequentially for improving map profile.

### CROSS-REFERENCE TO RELATED APPLICATIONS

This application claims priority to U.S. Provisional Patent Application Ser. No. 63/530,025, filed Jul. 31, 2023, and entitled WAFER PROCESSING APPARATUS WITH AUXILIARY GROUND PATHS, the disclosure of which is hereby incorporated by reference in its entirety.

### FIELD OF INVENTION

The present disclosure relates to a wafer processing apparatus, particularly to a wafer processing apparatus with the ability to improve the non-uniformity of the wafer by controlling the electric field with auxiliary ground paths located above a showerhead.

### BACKGROUND OF THE DISCLOSURE

A wafer processing apparatus using VHF (Very High Frequency) plasma may have a potential of new process with a high film quality with low temperature.

However, for VHF CCP (Capacitively Coupled Plasma) reactor for ALD and CVD applications, there may be a non-uniformity derived from standing wave effect.

This standing wave effect may cause center high plasma uniformity which affects the wafer deposited film uniformity.

To improve this non-uniformity, several solutions have been presented. However, previous solutions may not be easy to implement in the CCP environment.

Therefore, the present disclosure presents a wafer processing apparatus with auxiliary ground paths for improving non-uniformity.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a wafer processing apparatus comprising: a radio frequency (RF) enclosure enclosing and defining a reaction chamber; a showerhead placed inside of the reaction chamber configured to generating plasma for processing a wafer in the reaction chamber; a radio frequency (RF) power supply configured to generate RF and supply the generated RF to the showerhead; a plurality of capacitors connected in parallel and/or in serial between the RF power supply and the showerhead; and more than one auxiliary ground lines configured to be placed above the showerhead.

In accordance with another embodiment, more than one switches coupled to each of the more than one auxiliary ground lines individually and configured to let current flow or not to flow through the auxiliary ground line is provided.

In at least one aspect, a gap between the auxiliary ground line and the showerhead is between 2 mm and 15 mm.

In at least one aspect, a radius of the auxiliary ground line is between 2 mm and 10 mm.

In at least one aspect, a number of the auxiliary ground lines is between 3 and 10 and the auxiliary ground lines are placed around the showerhead with an equal angle.

In at least one aspect, the more than one switches coupled to the more than one auxiliary ground lines being configured to be turned on sequentially.

In accordance with another embodiment there may be provided, a radio frequency (RF) enclosure enclosing and defining a reaction chamber; a showerhead placed inside of the reaction chamber configured to generating plasma for processing a wafer in the reaction chamber; a radio frequency (RF) power supply configured to generate RF and supply the generated RF to the showerhead; a plurality of capacitors connected in parallel and/or in serial between the RF power supply and the showerhead; more than one auxiliary ground lines configured to be placed above the showerhead; and more than one switches coupled to each of the more than one auxiliary ground lines individually and configured to let current flow or not to flow through the auxiliary ground lines, wherein the more than one switches coupled to the more than one auxiliary ground lines being configured to be turned on sequentially to let a current flow or not to flow through the auxiliary ground line.

In at least one aspect, a gap between the auxiliary ground line and the showerhead is between 2 mm and 15 mm.

In at least one aspect, a radius of an auxiliary ground line is between 2 mm and 10 mm.

In at least one aspect, a number of the auxiliary ground lines is between 3 and 10 and the auxiliary ground lines are placed around the showerhead with an equal angle.

### BRIEF DESCRIPTION OF THE DRAWING FIGURES

The patent or application file contains at least one drawing executed in color. Copies of this patent or patent application publication with color drawing(s) will be provided by the Office upon request and payment of the necessary fee.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a wafer processing apparatus with an auxiliary ground path (line) according to an embodiment of the present disclosure.

FIG. 2 illustrates (a) a top-down view of 3 auxiliary ground paths located above showerhead with 120° according to an embodiment of the present disclosure and (b) a top-down view of 4 auxiliary ground paths located above showerhead with 90° according to another embodiment of the present disclosure.

FIG. 3 illustrates a side perspective view of the present disclosure's auxiliary ground path just above the showerhead according to an embodiment of the present disclosure.

FIG. 4 illustrates a top-down view of the present disclosure's auxiliary ground path's position relative to the showerhead it is located on and how far it is away from the showerhead according to an embodiment of the present disclosure.

FIG. 5 illustrates (a) a skewed map profile from an auxiliary ground path at 0° according to an embodiment of the present disclosure, (b) a skewed map profile from an auxiliary ground path at 120° according to an embodiment of the present disclosure, (c) a skewed map profile from an auxiliary ground path at 240° according to an embodiment of the present disclosure, and (d) an averaged map profile combined and averaged from FIG. 5(a)-FIG. 5(c) according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

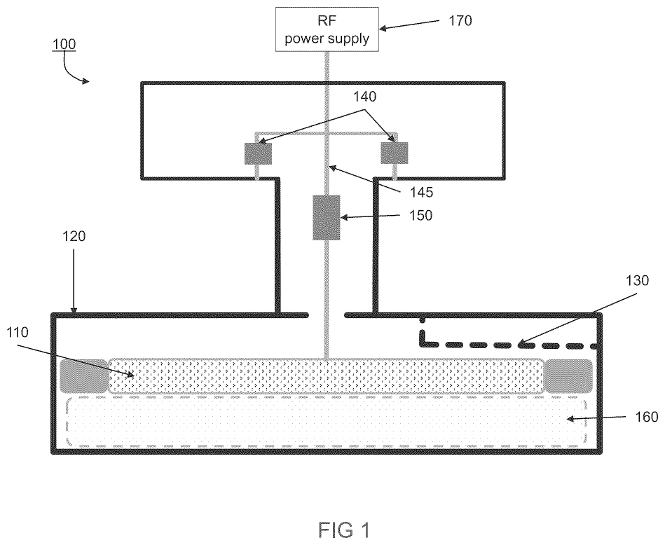

FIG. 1 illustrates an overall wafer processing apparatus setup 100 with an auxiliary ground path (line) according to an embodiment of the present disclosure.

The apparatus 100 comprises an RF power supply 170, RF enclosure 120 which encloses and defines reaction chamber, a showerhead (an electrode) 110, capacitors in parallel 140 and in series 150, and the auxiliary ground path (or line) 130.

The RF power supply 170 generates RF power and supplies it to the showerhead 110. The line 145 connects the RF power supply 170 and the showerhead 110.

The capacitors in parallel 140 and in series 150 are connected in the line 145 from the RF power supply 170 to the showerhead 110.

The capacitors 140, 150 may be connected differently (in number too) to control the impedance of the line 145. The showerhead 110 would generate plasma 160 for wafer processing.

The auxiliary ground path (AGP) 130 is installed below upper RF enclosure 120 and above the showerhead 110. The auxiliary ground path would be also called as auxiliary ground line.

Without AGP 130, the wafer profile would be affected mainly only by the showerhead's plasma generation capabilities, and this would result in a map profile with the thickest in the center (of the wafer which is processed) and the thickness is decreased outward.

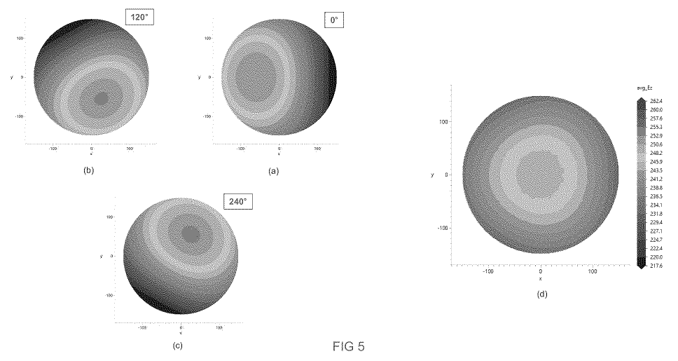

But with AGP 130, the map profile (of the wafer) is changed due to the E-field created by the AGP 130. These profiles will be explained with FIG. 5.

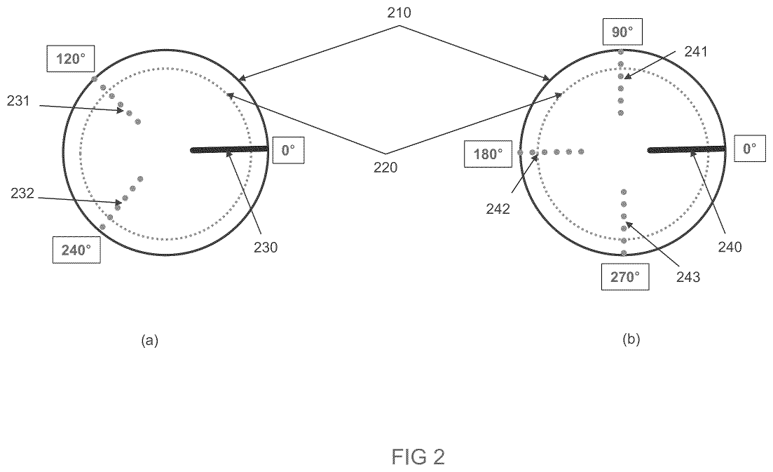

FIG. 2(a) and (b) illustrate the top down view of the apparatus with the number of auxiliary ground paths.

(a) is 3 (b) is 4. And the AGPs may be placed on the but since we are all along the individual profiles of the To control the profile, current may flow through the auxiliary ground path (or line) 130. The electric field generated from the AGP 130 w.

The RF enclosure 210 and showerhead 220 are viewed and in FIG. 2(a) the three (3) AGPs 230, 231, 232 are placed with 120 degrees of angles.

In FIG. 2(b), the four (4) AGPs 240, 241, 242, 243 are placed over the showerhead 220 with 90 degrees.

As shown in FIG. 2(a) and FIG. 2(b), the number of AGPs can be varied between 3 and 10 according to the map profile changes.

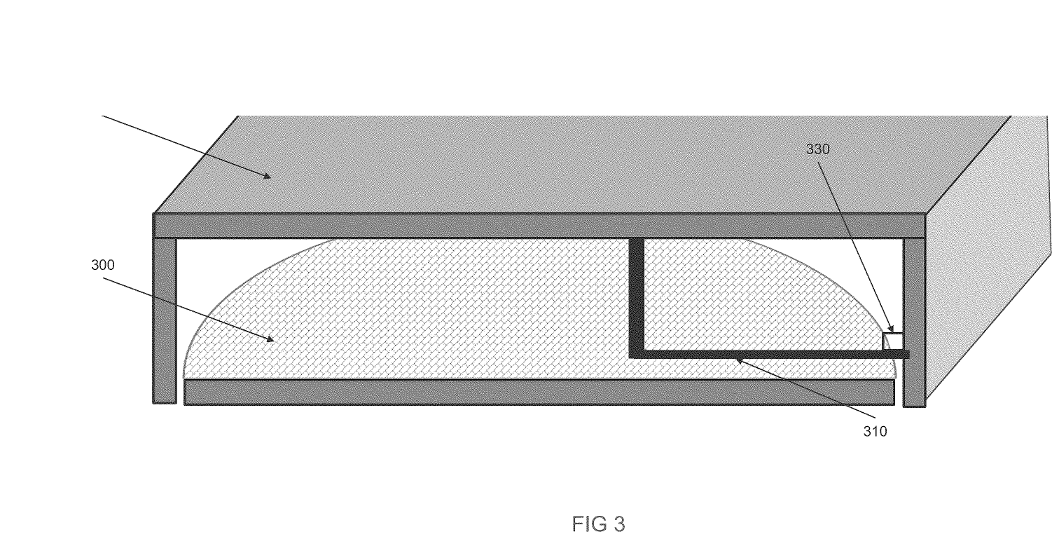

FIG. 3 illustrates the side view of the present disclosure.

A showerhead 300 is placed inside of a reaction chamber defined by RF enclosure 320. Also auxiliary ground line (or auxiliary ground path) 310 is placed just above the showerhead 300 and a switch 330 may be connected to the AGP 310 and may control whether current flows or not through the AGP 310.

When the switch 330 turns on and current flows through the AGP 310, the electric field created by the AGP 310 would be asymmetric due to the position of the AGP 310.

This asymmetry would be explained below with the drawings of FIG. 5.

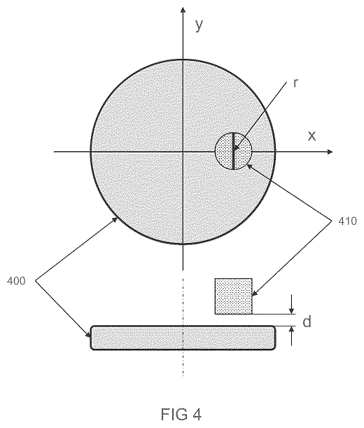

FIG. 4 illustrates a top-down view of the present disclosure's auxiliary ground path's position relative to the showerhead it is located on and how far it is away from the showerhead according to an embodiment of the present disclosure.

The showerhead 400 may be placed at the center of the x-y coordinate.

The x-y coordinate may be imaginary and used for measuring how far away the AGP 410 is located from its center (and the showerhead 400).

Usually, the AGP 410 has x coordinate between 30 mm and 150 mm and the gap (d) between the AGP 410 and the showerhead 400 would be between 2 mm and 15 mm.

The thickness (or radius, r) of the auxiliary ground path 410 is between 2 mm and 10 mm depending on the need of the intensity of electric field it creates.

FIG. 5(a)˜(d) illustrate a skewed map profile from an auxiliary ground path at 0°,a skewed map profile from an auxiliary ground path at 120°, a skewed map profile from an auxiliary ground path at 240°, and an averaged map profile combined and averaged from FIG. 5(a)-FIG. 5(c).

When an AGP placed at the degree 0 switched on (and the others off), the map profile would be shaped like FIG. 5(a) due to the strong electric field (E-field) generated from 0 degree-AGP. Also, when an AGP placed at the degree 120 switched on (and the others off), the map profile would be look like FIG. 5(b) due to the E-field it creates.

An AGP placed at the degree 240 would generate a map profile shown in FIG. 5(c) due to the E-field it creates when the others may be off.

Finally, when the switching sequence is controlled (the duration, the frequency and the sequence of on-time for each AGP), an averaged map profile looks like FIG. 5(d) which is rotationally symmetric.

The non-uniformity of FIG. 5(d) is 8% while the original non-uniformity is 18%.

The above-described arrangement of method is merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A wafer processing apparatus comprising:
a radio frequency (RF) enclosure enclosing and defining a reaction chamber;
a showerhead placed inside of the reaction chamber configured to generating plasma for processing a wafer in the reaction chamber;
a radio frequency (RF) power supply configured to generate RF and supply the generated RF to the showerhead;
a plurality of capacitors connected in parallel and/or in serial between the RF power supply and the showerhead; and
more than one auxiliary ground lines configured to be placed above the showerhead.

2. The wafer processing apparatus according to claim 1, further comprising:
more than one switches coupled to each of the more than one auxiliary ground lines individually and configured to let current flow or not to flow through the auxiliary ground line.

3. The wafer processing apparatus according to claim 1, wherein
a gap between the auxiliary ground line and the showerhead is between 2 mm and 15 mm.

4. The wafer processing apparatus according to claim 1, wherein
a radius of the auxiliary ground line is between 2 mm and 10 mm.

5. The wafer processing apparatus according to claim 1, wherein
a number of the auxiliary ground lines is between 3 and 10 and the auxiliary ground lines are placed around the showerhead with an equal angle.

6. The wafer processing apparatus according to claim 5, wherein
the more than one switches coupled to the more than one auxiliary ground lines being configured to be turned on sequentially.

7. A wafer processing apparatus comprising:
a radio frequency (RF) enclosure enclosing and defining a reaction chamber;
a showerhead placed inside of the reaction chamber configured to generating plasma for processing a wafer in the reaction chamber;
a radio frequency (RF) power supply configured to generate RF and supply the generated RF to the showerhead;
a plurality of capacitors connected in parallel and/or in serial between the RF power supply and the showerhead;
more than one auxiliary ground lines configured to be placed above the showerhead; and
more than one switches coupled to each of the more than one auxiliary ground lines individually and configured to let current flow or not to flow through the auxiliary ground lines,
wherein the more than one switches coupled to the more than one auxiliary ground lines being configured to be turned on sequentially to let a current flow or not to flow through the auxiliary ground line.

8. The wafer processing apparatus according to claim 7, wherein
a gap between the auxiliary ground line and the showerhead is between 2 mm and 15 mm.

9. The wafer processing apparatus according to claim 7, wherein
a radius of an auxiliary ground line is between 2 mm and 10 mm.

10. The wafer processing apparatus according to claim 7, wherein
a number of the auxiliary ground lines is between 3 and 10 and the auxiliary ground lines are placed around the showerhead with an equal angle.
